(19) United States
(12) Patent Application Publication
(10) Pub. No.: US 2002/0197829 A1
(43) Pub. Date: Dec. 26, 2002

(54) Method of manufacturing polycrystalline film and semiconductor device

(76) Inventors: Takashi Noguchi, Kanagawa (JP); Setsuo Usui, Kanagawa (JP); Yuka Akimoto, Kanagawa (JP)

Correspondence Address: SONNENSCHEIN NATH & ROSENTHAL, P.O. BOX 061080, WACKER DRIVE STATION, CHICAGO, IL, 60606-1080, US

(21) Appl. No.: 10/190,093

(22) Filed: Jul. 3, 2002

Related U.S. Application Data
(63) Continuation of application No. 09/666,707, filed on Sep. 21, 2000.

(30) Foreign Application Priority Data
Sep. 22, 1999 (JP) JP11-307438

(51) Int. Cl. C30B 1/00; H01L 21/20; H01L 21/36

(52) U.S. Cl. 438/487

(57) ABSTRACT

An amorphous film made of Si is formed on an insulating substrate sandwiching a protecting film in between and then a short-wave energy beam in pulse taking the form of an area beam is irradiated on the amorphous film to poly-crystallize, thereby obtaining a polycrystalline film. The number of shots of the short-wave energy beam on the same area of the polycrystalline film is between 2 and 60, more preferably 4 and 40. Therefore, a region in which (100) face is parallel to the substrate is obtained, and the region in which (100) face is parallel to the substrate is preferentially obtained. Also, the size of crystal grains is made larger. As a result, high-performance TFT's with uniform characteristics in which threshold is well controlled can be manufactured effectively.

### STATEMENT OF CROSS RELATED APPLICATIONS

This application is a continuation of and claims the benefit of the earlier filing date of U.S. Ser. No. 09/666,707, filed Sept. 21, 2000, which claims priority to JP11—307,438, filed 22 Sept. 1999, the disclosures of which are expressly incorporated by reference herein.

### BACKGROUND OF THE INVENTION

1. Field of the Invention

The present invention relates to a method of manufacturing a polycrystalline film and a method of manufacturing a semiconductor device. Specifically, the invention relates to a method of poly-crystallizing an amorphous film formed on a substrate by irradiating a short-wave energy beam in pulse taking the form of an area beam.

2. Description of the Related Art

In recent years, a display device with large size, fine definition and high-image quality display has been sought. Responding to these needs, an active matrix type display device in which a thin-film transistor (TFT) is employed as a switching device is used as a flat panel display (FDD) such as a liquid crystal display (LCD) or a organic electroluminescence display (O-ELD).

Examples of such TFT's used in this liquid crystal display are a TFT in which an amorphous silicon film is used for a channel region comprising an active layer and a TFT in which a polycrystalline silicon film is used for the channel region. The TFT using the polycrystalline silicon film has lower on-state resistance than the TFT using the amorphous silicon film and shows high responsivity and driving ability. Thus, this type of TFT is expected to lead to realization of a large size, fine definition and high-image quality display.

As a method of forming the polycrystalline silicon film, an excimer laser annealing (ELA) method for irradiating an excimer laser onto the amorphous silicon film is a well known example. With this ELA method, a multi-scan-shot annealing method to crystallize an area to be irradiated by irradiating an energy beam in line is widely performed.

However, with this method it is difficult to irradiate uniform energy beams in a scan direction (horizontal direction); therefore the grain size of crystal grains becomes non-uniform along a scan direction (I. Asai, N. Kato, M. Fuse, and H. Hamano, “A fabrication of homogenious poly-Si TFT's using excimer laser annealing”, in Extended Abst. Int. Conf. on Solid State Devices and Materials, Tsukuba, pp.55-57, 1992). Moreover, with a polycrystalline silicon film, the greater the grain size is, the greater mobility is, which is preferable, but there exists a problem such that when ELA is performed at ambient temperature, it is difficult to obtain sufficiently large crystal grain size of 400 nm or over, for example. Since (100) face has a smaller interface level density, threshold is well controlled in the (100) face; therefore, the (100) face is preferable for the interface between a crystalline silicon film and a gate insulating film (SiO₂). However, with this method, there is a problem such that a polycrystalline silicon film in which (111) face preferentially exists is formed in general.

In recent years, however, an ELA method using high-power energy beams, 10J and over has been developed (C. Prat, M. Stehle, and D. Zahorski, “1 Hz/15 Jules-excimer-laser development for flat panel display applications.” presented on May, 1999 in San Jose, USA). The large-area ELA for irradiating an energy beam taking the form of an area beam is a prominent method (T. Noguchi, T. Ogawa, Y. Ikeda, “Method of forming polycrystalline silicon layer on substrate by large area excimer laser irradiation”, U.S. Pat. No. 5,529,951, Jun. 25, 1996; T. Noguchi et al., IEEE Trans. On Electron Device, Vol. 43, pp. 1454-1458, 1996), which realizes formation of a medium-size or small-size LCD of 6 inches or smaller by irradiating the uniform large-area energy beam all at one time.

However, with the large-area ELA method using a beam taking the form of an area beam, it takes time to repeatedly irradiate an area to be irradiated and an energy beam in pulse is irradiated several times in the same area; thus the large-area ELA method has not been practical in terms of throughput. Moreover, it has been lately reported that a polycrystalline silicon film with larger crystal grain size was obtained by the ELA method (K. H. Lee et al., Gigantic crystal grain by excimer laser with long pulse duration of 200 ns and application to TFT, presented in ISPSA-98. Seoul). However, a controlling method for the (100) face to be parallel to a substrate has not been reported yet. It has been a desire to develop a method which can obtain a polycrystalline silicon film with larger crystal grain size including a region in which the (100) face is parallel to the substrate.

### SUMMARY OF THE INVENTION

The present invention has been achieved in view of the above problems. It is an object of the invention to provide a method of manufacturing a polycrystalline film and a method of manufacturing a semiconductor device in which a polycrystalline film with larger crystal grain size including a region whose specific crystal face is parallel to a substrate is obtained, and throughput is improved.

According to the method of manufacturing a polycrystalline film of the invention, a short-wave energy beam in pulse taking the form of an area beam is irradiated on an amorphous film including at least one of silicon and silicon germanium formed on a substrate to poly-crystallize, and the number of shots of the short-wave energy beam on the same area is between 2 and 60.

According to the method of manufacturing a polycrystalline film of another aspect of the invention, a short-wave energy beam in pulse taking the form of an area beam is irradiated on an amorphous film formed on a substrate to poly-crystallize and the polycrystalline film including a region whose specific crystal face is parallel to the substrate is formed by controlling the number of shots of the short-wave energy beam.

According to the method of manufacturing a semiconductor device of the invention, included is a step of forming a polycrystalline film which is poly-crystallized by irradiating a short-wave energy beam in pulse taking the form of an area beam on an amorphous film including at least one of silicon and silicon germanium formed on a substrate, wherein the number of shots of the short-wave energy beam on the same area is between 2 and 60.

According to the method of manufacturing a semiconductor device of another aspect of the invention, included is a step of forming a polycrystalline film by irradiating a short-wave energy beam in pulse taking the form of an area beam on an amorphous film formed on a substrate to poly-crystallize, and the polycrystalline film including a region whose specific crystal face is parallel to the substrate is formed by controlling the number of shots of the short-wave energy beam.

According to the method of manufacturing a polycrystalline film of still another aspect of the invention, a short-wave energy beam in pulse taking the form of an area beam is irradiated on an amorphous film including at least one of silicon and silicon germanium to poly-crystallize, and the number of shots of the short-wave energy beam on the same area is between 2 and 60.

According to the method of manufacturing a polycrystalline film of yet another aspect of the invention, a short-wave energy beam in pulse taking the form of an area beam is irradiated on an amorphous film to poly-crystallize and the polycrystalline film including a region whose specific crystal face is parallel to the substrate is formed by controlling the number of shots of the short-wave energy beam.

In the method of manufacturing a semiconductor device of the present invention, the method of manufacturing a polycrystalline film of the present invention is used.

Other and further objects, features and advantages of the invention will appear more fully from the following description.

### BRIEF DESCRIPTION OF THE DRAWINGS

FIG. 1 is a block diagram schematically showing the structure of a liquid crystal display device manufactured by using a method of manufacturing a polycrystalline film and a method of manufacturing a semiconductor device according to an embodiment of the present invention.

FIGS. 2A and 2B are perspective views showing each step of the method of manufacturing a polycrystalline film and the method of manufacturing a semiconductor device of the embodiment of the present invention.

FIG. 3 is a TEM micrograph of a surface of a test sample.

FIG. 4 schematically shows a distinctive portion of the TEM micrograph shown in FIG. 3.

FIG. 5 is a characteristic diagram showing the relation between the number of shots of a short-wave energy beam and the orientation of crystal faces.

FIG. 6 is a characteristic diagram showing the relation between the number of shots of the short-wave energy beam and the average size of crystal grains.

### DETAILED DESCRIPTION OF THE PREFERRED EMBODIMENTS

An embodiment of the present invention will be described in detail below with reference to the accompanying drawings.

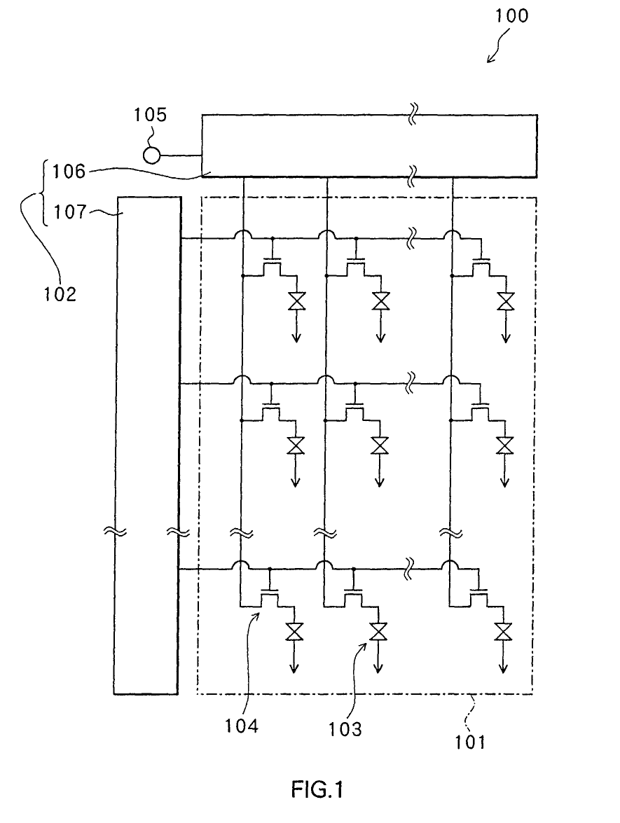

In the embodiment below, the case where a liquid crystal display 100 shown in FIG. 1 is, for example, fabricated as a semiconductor device will be concretely described. The liquid crystal display 100 includes a pixel area 101 and a peripheral circuit area 102 which is provided on the periphery of the pixel area 101 on a substrate (not shown). Formed in the pixel area 101 are a crystal liquid layer 103 and a plurality of thin film transistors 104 arranged in matrix for driving the liquid crystal layer 103 in accordance with each pixel. The peripheral circuit area 102 having a video signal terminal 105 includes a horizontal scan area (horizontal scan circuit; signal electrode driving circuit) 106 for transmitting a horizontal scan signal along with an inputted image signal to the pixel area 101, and a vertical scan area (vertical scan circuit; scan electrode driving circuit) 107 for transmitting a vertical scan signal to the pixel area 101.

In the liquid crystal display 100 the image signal is transmitted to the horizontal scan area 106 through the video signal terminal 105. The horizontal scan signal along with the image signal from the horizontal scan area 106 and the vertical scan signal from the vertical scan area 107 are transmitted to the thin-film transistors 104 corresponding to each pixel in the pixel area 101. Accordingly, switching in the liquid crystal layer 103 is controlled; thus, image display is performed.

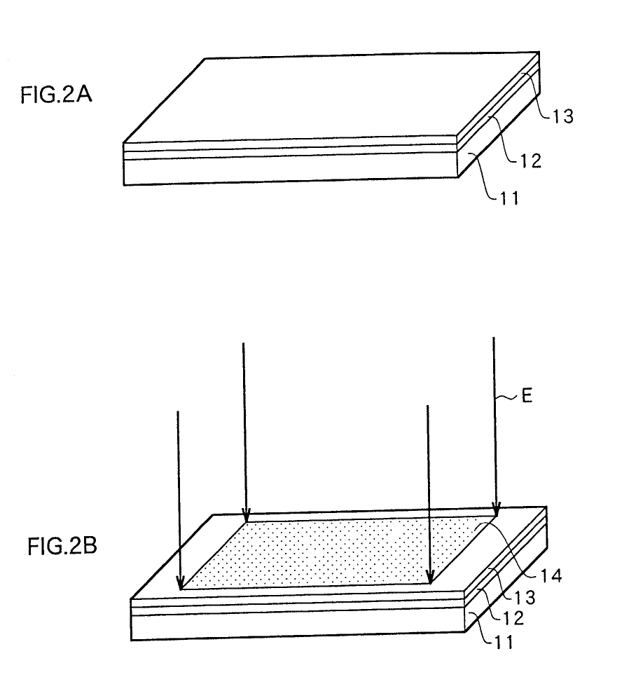

FIGS. 2A and 2B show each step of the method of manufacturing a polycrystalline film and the method of manufacturing a semiconductor device according to the embodiment. In the method of manufacturing a semiconductor device, the method of manufacturing a polycrystalline film is employed. As illustrated in FIG. 2A, with the embodiment of the present invention an amorphous film 13 made of silicon (Si) is formed on the whole surface of an insulating substrate 11 made of glass sandwiching a 40 nm thick protecting film 12 in a direction along which layers are stacked (simply referred to thickness herein later), for example. The protecting film 12 is formed, for example, by stacking a silicon nitride (SiN) film of 10 nm in thickness and a silicon dioxide (SiO₂) film of 30 nm in thickness in sequence from the side of the substrate 11 for the purpose of preventing the amorphous film 13 (that is, a polycrystalline film herein after) from being contaminated by the substrate 11 made of glass. The protecting film 12 is formed, for example, by a chemical vapor deposition (CVD) method and a sputter method. □

The amorphous film 13 is formed by, for example, a CVD method, a plasma enhanced chemical vapor deposition method or a sputtering method. The thickness of the amorphous film 13 is preferably, for example, between 10 nm and 100 nm, more preferably, between 15 nm and 750 nm, which makes it possible to obtain a preferable polycrystalline film 14 in the subsequent process for poly-crystallization. Here, the thickness of the amorphous film 13 is 40 nm, for example.

When the amorphous film 13 is formed by the plasma CVD method, the amorphous film 13 contains a great amount of hydrogen. Therefore, it is preferable to remove hydrogen by, for example, performing a heat treatment at a temperature of 450□ for two hours or performing rapid thermal annealing (RTA) with ultra violet rays after forming the amorphous film 13.

Subsequently, as shown in FIG. 2B a short-wave energy beam E in pulse taking the form of an area beam is irradiated on the amorphous film 13 to crystallize, thereby forming the polycrystalline film 14, for example. Here, the area beam denotes a beam having an area larger than a fixed area on the surface to be irradiated and the shape of the beam on the surface to be irradiated may be rectangular, circular, ellipse, or the like. The specific size of the area beam on the surface to be irradiated is, for example, 1.5 cm² or over, preferably, 10 cm² or over, more preferably 15 cm² or over.

As described above, when the region to be poly-crystallized is not very large (for example, 6 inches or less), using the area beam enables the whole region to be poly-crystallized at the same time. When the region to be poly-crystallized is larger than the area of the short-wave energy beam E, the region is poly-crystallized by irradiating the short-wave energy beam E while shifting. In the embodiment, a region for pixel area formation and a region for peripheral circuit area formation may be poly-crystallized at the same time or may be poly-crystallized separately.

As the short-wave energy beam E, for example, an excimer laser beam is appropriate. More specifically, a XeCl excimer laser (308 nm) with a pulse frequency of 10 Hz or over is generated using an X-ray reserve ionization method, for example, and an area beam is shaped so as to be uniformly existing in a rectangular space of 4 cm×4 cm and irradiated on the amorphous film 13, for example.

When irradiating the short-wave energy beam E, it is preferable that controlling the number of pulse shots enables the polycrystalline film 14 to include a region in which (100) face is parallel to the substrate 11 (specifically, the surface of the substrate 11 to be stacked), that is, the polycrystalline film 14 includes a region in which the bearing of (100) face is identical to a direction along which layers are stacked by controlling the pulse shot number. The polycrystalline film 14 preferentially includes the region in which (100) face is parallel to the substrate 11. More specifically, the number of shots of the short-wave energy beam E on the same area is controlled to be between 2 and 60, more preferably, between 4 and 40. That is for the following reason: The bearing of the crystal face which is preferentially observed differs depending on the number of irradiation shots. Therefore, within a certain range of the number of irradiation shots a region whose (100) face, where threshold is well controlled, is parallel to the substrate 11 can be formed and the crystal grain size can be made larger. Here, the “being parallel” includes a state of being parallel with some error.

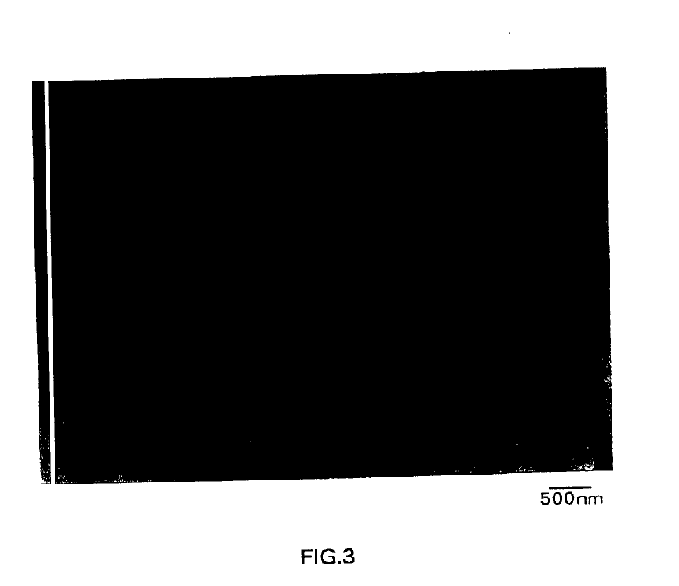

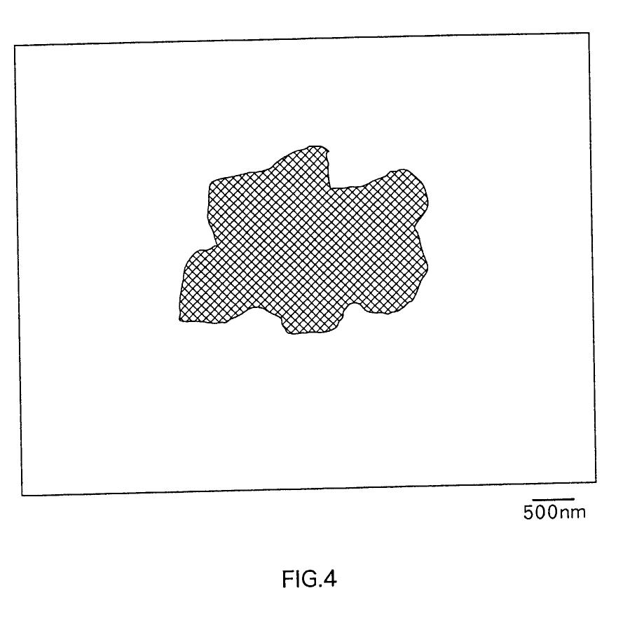

FIG. 3 is a micrograph showing the surface of a sample taken by a transmission electron microscope (TEM). FIG. 4 shows a distinctive portion of the TEM micrograph shown in FIG. 3. This sample was obtained by irradiating the area short-wave energy beam E on a silicon amorphous film of about 40 nm in thickness under the following condition.

Condition for Irradiation

| | |
|---|---|
| Energy beam: | XeCl excimer laser beam (308 nm) |
| Pulse frequency: | ⅙ Hz |
| Pulse width: | 200 nsec |
| Energy density: | 550 mJ/cm² per 1 pulse |
| Number of shots: | 30 times |

In FIG. 3 the region corresponding to the hatched portion in FIG. 4 is one crystal grain. On this crystal grain, orientation of crystal faces was examined by a selected area electron diffraction (SAED) method using a transmission electron microscope (TEM). The (100) face was parallel to the substrate. Accordingly, it was found that controlling the number of shots of irradiation makes it possible to obtain crystal grains whose (100) face is parallel to the substrate. With regard to crystal grains of this sample, the maximum grain size is 2 μm or over and the average grain size is about 800 nm which shows that the crystal grain size can be made larger by controlling the number of shots of irradiation. The size of the crystal grain shown in FIG. 3 is approximately 2.8 μm.

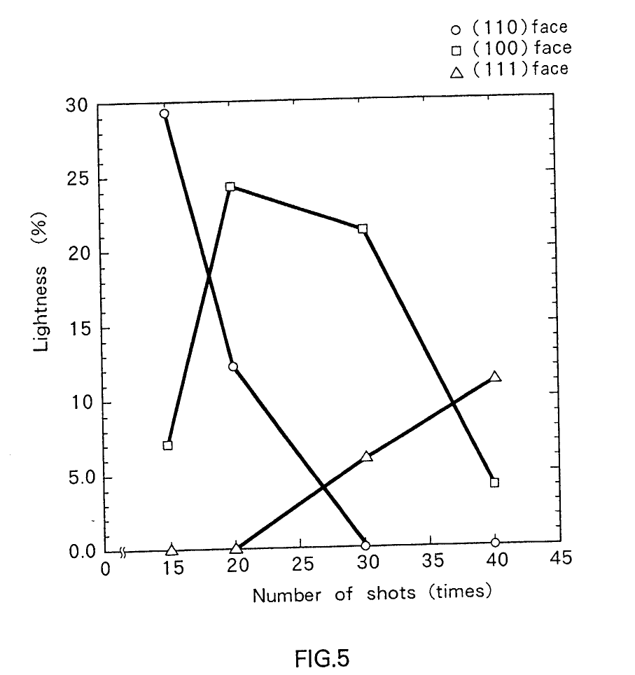

FIG. 5 is a test result showing the relation between the number of shots of the short-wave energy beam E and orientation of crystal faces. Orientation of crystal faces was examined on the test sample shown in FIG. 3 and other samples onto which the short-wave energy beam E was irradiated under the same condition except that test samples and the number of shots of irradiation were changed, respectively. The orientation of the crystal faces was obtained by measuring the lightness (intensity) of a diffraction ring of each face bearing by a reflection high energy electron diffraction (RHEED) method. With this method, the greater the lightness is, the higher the existing rate of the crystal face parallel to the substrate is. The vertical axis of FIG. 5 is lightness of each face bearing obtained by the RHEED method.

As seem from FIG. 5, when the number of shots of the short-wave energy beam E is low, a region in which (110) face is parallel to the substrate is preferentially observed. As the number of shots of irradiation increases, the region in which (100) face is parallel to the substrate increases. When the number of shots of irradiation exceeds a certain number, the region in which (100) face is parallel to the substrate starts to decrease. When the number of shots of irradiation further increases, a region in which (111) face is parallel to the substrate is preferentially observed. That is, it is found that controlling the number of shots of irradiation enables at least part of (100) face to become parallel to the substrate, and to be preferentially parallel to the substrate. Incidentally, in the specification the “preferentially” denotes a state in which the existing rate is highest among the crystal faces parallel to the substrate, for example.

Incidentally, the orientation of crystal faces can be obtained by the aforementioned SAED (TEM) method or X-ray diffraction (XRD) method in addition to the RHEED method. With regard to each test sample above, the orientation of crystal faces was examined by the SAED (TEM) method. The result was the same as that obtained from the RHEED method.

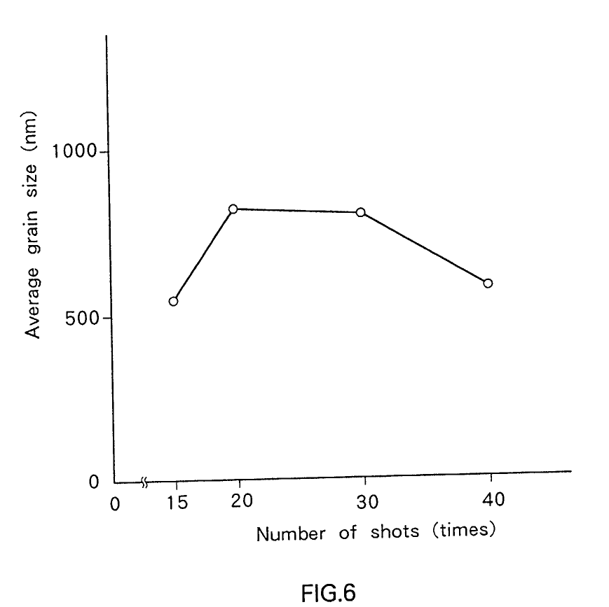

Further, FIG. 6 is a test result showing the relation between the number of shots of the short-wave energy beam E and the average size of crystal grains. In this test result, the average crystal grain size of each test sample shown in FIG. 5 was obtained. The average size of the crystal grains was determined by the results observed by the TEM.

As seen from FIG. 6, a tendency is observed such that as the number of shots of the short-wave energy beam E increases, the average size of crystal grains becomes large, and when exceeding a certain number of shots, the average size of crystal grains inversely becomes small. When FIGS. 5 and 6 are compared, the number of shots at which greater crystal grain size is obtained is largely equal to the number of shots of irradiation at which (100) face becomes preferentially parallel to the substrate. That is, controlling the number of shots of irradiation enables the region in which (100) face is parallel to the substrate to exist and the crystal grain size to become larger.

Although the reason for the above phenomenon is unknown, it is considered to be for the following reasons: Nucleation and growth of smaller crystal grains occur by the initial irradiation of the short-wave energy beam E. As the number of shots of irradiation increases, smaller grains emerge with each other and grow to have a certain crystal grain size. This is because when the number of shots of the irradiation exceeds a certain number, the size of crystal grains becomes fairly large compared to the thickness of the film; therefore, growth of secondary crystal grains occurs around the melting point at which surface energy is the minimum. In this case, it is considered that four side surfaces of (100) face in the grain whose (100) face is parallel to the substrate are (200) oriented (refer to T. Noguchi et.al., Possibility of QSC semiconductor films, published in Proc. of Mat. Res. Soc. Vol. 557 (1999); presented in MRS Spring meeting A18. 7: 1999 San Francisco). Consequently, when grains are melted and revolved to be regulated by the irradiation of the short-wave energy beam E, grain boundaries are prone to be lattice-matched, thereby forming larger crystal grains of approximately 1 μm. However, as the number of shots of irradiation further increases, surface roughness increases involving natural oxidation films or oxygen or water vapor in the air. Therefore, the energy-stable (111) face with least dangling-bond becomes parallel to the substrate in the end (refer to J. H. Kim and J. Y. Lee, Thin Sold Films 292,313, 1997).

Incidentally, the energy density per one pulse of the short-wave energy beam E is preferably within a range of 100 mJ/cm² and 850 mJ/cm², more preferably within a range of 200 mJ/cm² and 800 mJ/cm². The width of pulse is preferably within a range of 100 nsec and 300 nsec. This is because when the energy density per one pulse of the short-wave energy beam E and the pulse width fall within the aforementioned range, the orientation of the crystal faces can be easily controlled. Incidentally, the shorter pulse width improves efficiency, which is preferable. The pulse frequency is preferably 1 Hz or over for improving throughput.

After the polycrystalline film 14 is formed as described, steps for forming TFT's, steps for manufacturing a liquid crystal display device and the like are performed by a well known method. These steps include formation of a gate oxidation film after separating devices, formation of a source region and a drain region after formation of a gate electrode, formation of a layer insulating film, formation of a contact hole, formation of metal wiring and indium-tin oxide (ITO), sealing of liquid crystal and the like. Thus, the process for the method of manufacturing a polycrystalline film and the method of manufacturing a semiconductor device according to the present embodiment is completed, finishing the semiconductor device shown in FIG. 3 is.

As described, according to the embodiment the number of shots of the short-wave energy beam E on the same area is controlled to be between 2 and 60, more preferably, between 4 and 40; therefore, it is possible to include the region in which (100) face is parallel to the substrate 11 and to preferentially include the region in which (100) face is parallel to the substrate 11. Also, the crystal grain size is made larger and throughput is improved. Accordingly, high-performance TFT's with uniform characteristics in which threshold is well controlled can be manufactured with great throughput. The liquid crystal display 100 with uniform characteristics which has a large area and realizes high-definition display is manufactured with great throughput.

The polycrystalline film 14 includes the region in which (100) face is made parallel to the substrate 11 by controlling the number of shots of the short-wave energy beam E; therefore, the polycrystalline film 14 with larger crystal grain size in which the characteristics of (100) face is utilized can be formed with great throughput. Consequently, as described high-performance TFT's with uniform characteristics in which threshold is well controlled can be manufactured with great throughput.

When making the thickness of the amorphous film 13 between 10 nm and 100 nm, preferable polycrystalline film 14 can be obtained. Furthermore, by making the thickness of the amorphous film 13 between 15 nm and 750 nm, higher effects can be obtained.

When making the energy density per one pulse of the short-wave energy beam E fall within a range between 100 J/cm² and 850 J/cm², more preferably between 200 mJ/cm² and 800 mJ/cm², the orientation of the crystal faces in the polycrystalline film 14 can be easily controlled.

Although the present invention has been described above by exemplifying the embodiment, the present invention is not limited to the above described embodiment and various modification are possible. For example, in the above embodiment described is a case where the amorphous layer 13 is made of silicon. However, not only the single layer structure with silicon but also a structure such that a silicon film is stacked on a silicon germanium (SiGe) film may be possible, for example. More specifically, the present invention may be widely applied to a case where an amorphous layer including at least one of silicon and silicon germanium is to be poly-crystallized. In this case, the crystal face which becomes parallel to the substrate by controlling the number of shots of the short-wave energy beam E is the same as the one in the above embodiment.

Although in the above embodiment the substrate 11 is made of glass, the substrate 11 may be made of other materials such as plastic or single crystal silicon, or a low-cost substrate in which a dioxide silicon film is formed on a surface of a silicon wafer may be used.

Furthermore, in the above embodiment described is a case where the monolithic crystal liquid display 100 in which the pixel area 101, and the peripheral circuit area 102 are formed on the same substrate is manufactured. However, the present invention may be applied to a liquid crystal display having other structures such as a liquid crystal display in which a pixel area and a peripheral circuit area are formed on separate substrates, or a liquid crystal display in which a pixel area, a peripheral circuit area and other function circuits are formed on the same substrate. Further, the present invention may be also applied to other active matrix type flat panel displays such as an organic electroluminescence display. Moreover, although in the above described embodiment described is a case where the liquid crystal display 100 is manufactured as a semiconductor device, the present invention may be widely applied to a case where other semiconductor devices such as a large scale integrated circuit (LSI) are manufactured. In this case, when an amorphous film made of a material other than silicon or silicon germanium is poly-crystallized, for example, the present invention may be applied. Further, it is preferable that a specific preferred crystal face includes a region parallel to the substrate by controlling the number of shots of the short-wave energy beam.

As described above, according to the method of manufacturing a polycrystalline film and the method of manufacturing a semiconductor device of the invention, the number of shots of the short-wave energy beam on the same area is between 2 and 60. Therefore, the region in which (100) face is parallel to the substrate is included or is preferentially included. Also, the crystal grain size is made larger and throughput is improved. Accordingly, high-performance TFT's with uniform characteristics in which threshold is well controlled are manufactured with great throughput, and a large-size liquid crystal display with high-definition display and uniform characteristics is realized with great throughput, for example.

According to the method of manufacturing a polycrystalline film and the method of manufacturing a semiconductor device of another aspect of the invention, by controlling the number of shots of the short-wave energy beam the region in which the specific crystal face is parallel to the substrate is included; therefore, the polycrystalline film in which characteristics of the specific crystal face is utilized is formed with great throughput. Accordingly, similar to the above-described aspects of the invention, superior TFT's are manufactured with great throughput, for example.

Obviously many modifications and variations of the present invention are possible in the light of the above teachings. It is therefore to be understood that within the scope of the appended claims the invention may be practiced otherwise than as specifically described.

What is claimed is:

1. A method of manufacturing a polycrystalline film, wherein a short-wave energy beam in pulse taking the form of an area beam is irradiated on an amorphous film including at least one of silicon and silicon germanium formed on a substrate to poly-crystallize, and the number of shots of the short-wave energy beam on the same area is between 2 and 60.

2. The method of claim 1, wherein the polycrystalline film including a region in which a (100) face is parallel to the substrate is formed by irradiating the short-wave energy beam.

3. The method of claim 1, wherein the polycrystalline film preferentially including a region in which a (100) face is parallel to the substrate is formed by irradiating the short- wave energy beam.

4. The method of claim 1, wherein the amorphous film is formed having a thickness between 10 nm and 100 nm.

5. The method of claim 1, wherein the short-wave energy beam is irradiated at an energy density between 100 mJ/cm² and 850 mJ/cm².

6. A method of manufacturing a polycrystalline film, wherein a short-wave energy beam in pulse taking the form of an area beam is irradiated on an amorphous film which is formed on a substrate to poly-crystallize, and
the polycrystalline film including a region whose specific crystal face is parallel to the substrate is formed by controlling the number of shots of the short-wave energy beam.

7. A method of manufacturing a semiconductor device, comprising a step of forming a polycrystalline film which is poly-crystallized by irradiating a short-wave energy beam in pulse taking the form of an area beam on an amorphous film including at least one of silicon and silicon germanium formed on a substrate, wherein the number of shots of the short-wave energy beam on the same area is between 2 and 60.

8. A method of manufacturing a semiconductor device, comprising a step of forming a polycrystalline film by irradiating a short-wave energy beam in pulse taking the form of an area beam on an amorphous film formed on a substrate to poly-crystallize,
wherein the polycrystalline film including a region whose specific crystal face is parallel to the substrate is formed by controlling the number of shots of the short-wave energy beam.
